(19) United States
(12) Patent Application Publication
(10) Pub. No.: US 2011/0215348 A1
(43) Pub. Date: Sep. 8, 2011

(54) Reflection Mode Package for Optical Devices Using Gallium and Nitrogen Containing Materials

(75) Inventors: Troy Anthony Trottier, Fremont, CA (US); Michael Ragan Krames, Los Altos, CA (US); Rajat Sharma, Fremont, CA (US); Frank Tin Chung Shum, Sunnyvale, CA (US); Rakesh Venkatesh, Oakland, CA (US)

(73) Assignee: Soraa, Inc., Fremont, CA (US)

(21) Appl. No.: 13/019,521

(22) Filed: Feb. 2, 2011

Related U.S. Application Data
(60) Provisional application No. 61/301,183, filed on Feb. 3, 2010.

(51) Int. Cl. H01L 33/08; B82Y 99/00; B82Y 20/00

(52) U.S. Cl. 257/89; 977/774; 977/950; 257/E33.005

(57) ABSTRACT

An optical device includes an LED formed on a substrate and a wavelength conversion material, which may be stacked or pixilated, within vicinity of the LED. A wavelength selective surface blocks direct emission of the LED device and transmits selected wavelengths of emission caused by an interaction with the wavelength conversion material.

### CROSS-REFERENCE TO RELATED APPLICATIONS

This application claims priority to U.S. Provisional Patent Application No. 61/301,183, filed Feb. 3, 2010, commonly assigned and incorporated by reference hereby for all purposes. Also incorporated by reference are commonly assigned patent application Ser. Nos. 12/887,207; 12/914,789; 61/257,303; 61/256,934; and 61/241,459.

### BACKGROUND OF THE INVENTION

This invention relates generally to lighting. The invention provides techniques for transmitting electromagnetic radiation from LED devices, such as ultra-violet, violet, blue, blue and yellow, or blue and green. The devices may be fabricated on bulk semipolar or nonpolar materials with use of phosphors, which emit light in a reflection mode. In other embodiments, the starting materials can include polar gallium nitride containing materials. The invention can be applied to white lighting, multi-colored lighting, general illumination, decorative lighting, automotive and aircraft lamps, street lights, lighting for plant growth, indicator lights, lighting for flat panel displays, other optoelectronic devices, and the like.

In the late 1800's, Thomas Edison invented the light bulb. The conventional light bulb, commonly called the “Edison bulb,” uses a tungsten filament enclosed in a glass bulb sealed in a base, which is screwed into a socket. The socket is coupled to a power source. The conventional light bulb is in widespread use. Unfortunately, the conventional light bulb dissipates more than 90% of the energy used as thermal energy. Additionally, the conventional light bulb routinely fails due to thermal expansion and contraction of the filament element.

Fluorescent lighting uses a tube structure filled with a noble gas and typically also contains mercury. A pair of electrodes is coupled to the tube and to an alternating power source through a ballast. When the mercury vapor is excited, it discharges, emitting deep ultraviolet light. The tube is coated with phosphors, which are excited by the ultraviolet light. More recently, fluorescent lighting has been fitted onto a base structure, which couples into a standard socket.

Solid state lighting techniques have also been used. Solid state lighting relies upon semiconductor materials to produce light emitting diodes, commonly called LEDs. At first, red LEDs were demonstrated and introduced into commerce. Red LEDs use Aluminum Indium Gallium Phosphide or AlInGaP semiconductor materials. Most recently, Shuji Nakamura pioneered the use of InGaN materials to produce LEDs emitting light in the blue color range for blue LEDs. The blue colored LEDs led to innovations such as solid state lighting and the blue laser diode, which in turn enabled the Blu-Ray™ DVD player, and other developments. Other color LEDs have also been proposed.

High intensity UV, blue, and green LEDs based on GaN have been proposed and demonstrated with some success. Efficiencies have typically been highest in the UV-violet, dropping off as the emission wavelength increases to blue or green. Unfortunately, achieving high intensity, high-efficiency GaN-based green LEDs has been problematic. The light emission efficiency of typical GaN-based LEDs drops off significantly at higher current densities, as are required for general illumination applications, a phenomenon known as “roll-over.” Additionally, packages incorporating LEDs also have limitations. Such packages often have thermal inefficiencies. Other limitations include poor yields, low efficiencies, and reliability issues. Although highly successful, solid state lighting techniques must be improved for full exploitation of their potential.

### BRIEF SUMMARY OF THE INVENTION

In selected embodiments the invention provides an optical device having a mounting member with a surface region, at least one LED device overlying a portion of the surface region, and a wavelength conversion material disposed over the surface region, a wavelength selective surface configured to reflect substantially direct emission of the LED device and configured to transmit at least one selected wavelength of converted emission caused by an interaction with at least the wavelength conversion material and the direct emission of the LED device. At least 30% of the direct emission from the LED device is reflected from the wavelength selective surface prior to interacting with the wavelength conversion material. Preferably the wavelength material has a thickness of less than 100 um, but it can be less than 200 um, and the LED device has a surface region which extends higher than the surface of the wavelength conversion material. The wavelength conversion material preferably includes wavelength conversion particles characterized by an average particle-to-particle distance of about less than 10 times the average particle size of all the wavelength-conversion materials.

Typically, the wavelength selective surface is a filter or a dichroic optical member. The wavelength conversion material can be provided as first and second wavelength-conversion material arranged in a pixilated pattern, mixed together, or provided in a stacked arrangement. The wavelength conversion material can be provided as quantum dots, phosphor material, or organic material. Also preferably, the LED device is fabricated on gallium and nitrogen containing substrate having a polar, semi-polar, or non-polar orientation.

In another embodiment, the optical device includes a mounting member having a surface region, an LED device disposed over a portion of the surface region together with a layer of wavelength conversion material. A wavelength selective surface is configured to reflect substantially direct emission of the LED device and transmit selected wavelengths of converted emission caused by an interaction with the wavelength conversion material by the direct emission of the LED device. A first volume formed by the LED surface area at a first height connects the LED surface and the wavelength selective surface. A second volume formed by an area of the layer of wavelength conversion material at a second height connects the layer of wavelength conversion material and wavelength selective surface. The second volume is greater than the first volume, and the second region is substantially transparent and substantially free from wavelength conversion materials.

The invention provides an optical device which includes a mounting member having a surface region and LED devices over the surface region. Exposed portions of the surface region have first wavelength conversion material disposed over them and second wavelength conversion material disposed over the first wavelength conversion material. A wavelength selective surface blocks substantially direct emission from the LED devices and transmits selected wavelengths of reflected emission caused by an interaction with the wavelength conversion materials.

In an alternative embodiment, the device has a plurality of wavelength conversion materials provided within a vicinity of the LED devices. A wavelength selective surface blocks direct emission of the LEDs, while transmitting selected wavelengths of reflected emission caused by an interaction with the wavelength conversion materials. Preferably, the LED devices are mounted so that their upper surface is above the upper surface of the wavelength conversion materials. The wavelength conversion materials can be configured as a pixelated structure, mixed together, or stacked one atop the other.

In other embodiments the mounting member has exposed portions of the surface region and a thickness of ductile material overlying the exposed portions. The ductile material can include soft or hard metals, semiconductors, polymers or plastics, dielectrics, or combinations of these. A wavelength conversion material is partially or fully embedded within the ductile material. A wavelength selective surface blocks direct emission of the LED devices and transmits selected wavelengths of reflected emission caused by an interaction with the wavelength conversion material. The ductile material and the wavelength conversion material are arranged to have appropriate heights with respect to each other.

The invention also provides a method of manufacturing optical devices. The method includes providing a mounting member having a surface region and forming a thickness of carrier material with wavelength convention materials therein, for example, using an electroplating-like process or deposition process. The wavelength conversion material is preferably then exposed by a suitable process step. In another embodiment, the device has matrices coupled to the wavelength conversion materials and an average bulk thermal conductivity. The matrices can include silicone, epoxy, or other encapsulant material, which may be organic or inorganic, to include wavelength conversion materials such as phosphors.

The present device and method provides for an improved lighting with improved efficiency. The method and resulting structure are easier to implement using conventional technologies. In a specific embodiment, a violet-emitting LED device is capable of emitting electromagnetic radiation at a wavelength range from about 380 nanometers to about 440 nanometers. In another embodiment, a blue-emitting LED device is capable of emitting electromagnetic radiation at a wavelength range from about 440 nanometers to about 490 nm. In other embodiments, a plurality of LED devices with a plurality of emission wavelengths are employed.

### BRIEF DESCRIPTION OF THE DRAWINGS

FIG. 1 is a simplified diagram of packaged light emitting devices using a flat carrier and cut carrier;

FIGS. 2 through 12 are diagrams of alternative packaged light emitting devices using reflection mode configurations;

FIGS. 13 through 15 are diagrams of packaged light emitting devices using reflection mode configurations according to other embodiments of the invention; and

FIGS. 16 through 22 are diagrams of methods for applying wavelength conversion materials.

### DETAILED DESCRIPTION OF THE INVENTION

Recent breakthroughs in GaN-based optoelectronics demonstrate the potential of devices fabricated on bulk GaN substrates, including polar, nonpolar and semipolar orientations. For nonpolar and semipolar orientations, lack of strong polarization induced electric fields that plague conventional devices on c-plane (i.e., polar) GaN leads to a greatly enhanced radiative recombination efficiency in the light emitting InGaN layers. Furthermore, the nature of the electronic band structure and the anisotropic in-plane strain leads to highly polarized light emission, which offers advantages in applications such as display backlighting.

Of particular importance to the field of lighting is the progress of light emitting diodes (LED) fabricated on nonpolar and semipolar GaN substrates. Such devices making use of InGaN light emitting layers have exhibited record output powers at extended operation wavelengths into the violet region (390-430 nm), the blue region (430-490 nm), the green region (490-560 nm), and the yellow region (560-600 nm). For example, a violet LED, with a peak emission wavelength of 402 nm, was recently fabricated on an m-plane (1-100) GaN substrate and demonstrated greater than 45% external quantum efficiency, despite having no light extraction enhancement features, and showed excellent performance at high current densities, with minimal roll-over. With high-performance bulk-GaN-based LEDs, several types of white light sources are now possible. In one implementation, a violet-emitting bulk-GaN-based LED is packaged together with phosphors. Preferably, the phosphor is a blend of three phosphors, emitting in the blue, the green, and the red, or sub-combinations thereof.

A polar, non-polar or semi-polar LED may be fabricated on a bulk gallium nitride substrate. The gallium nitride substrate is usually sliced from a boule that was grown by hydride vapor phase epitaxy or ammonothermally, according to methods known in the art. The gallium nitride substrate can also be fabricated by a combination of hydride vapor phase epitaxy and ammonothermal growth, as disclosed in U.S. patent application Ser. No. 61/078,704, commonly assigned, and hereby incorporated by reference. The boule may be grown in the c-direction, the m-direction, the a-direction, or in a semi-polar direction on a single-crystal seed crystal. Semipolar planes may be designated by (hkil) Miller indices, where i=−(h+k), l is nonzero and at least one of h and k are nonzero. The gallium nitride substrate may be cut, lapped, polished, and chemical-mechanically polished. The gallium nitride substrate orientation may be within ±5 degrees, ±2 degrees, ±1 degree, or ±0.5 degrees of the {1-100} m plane, the {11-20} a plane, the {11-22} plane, the {20-2±1} plane, the {1-10±1} plane, the {1-10-±2} plane, or the {1-10±3} plane. The gallium nitride substrate preferably has a low dislocation density.

A homoepitaxial polar, non-polar or semi-polar LED is fabricated on the gallium nitride substrate according to methods that are known in the art, for example, following the methods disclosed in U.S. Pat. No. 7,053,413, which is hereby incorporated by reference in its entirety. At least one AlₓIn_{y}Ga_{1-x-y}N layer, where 0≦x23 1, 0≦y≦1, and 0≦x+y≦1, is deposited on the substrate, for example, following the methods disclosed by U.S. Pat. Nos. 7,338,828 and 7,220,324, which are hereby incorporated by reference in their entirety. The at least one AlₓIn_{y}Ga_{1-x-y}N layer may be deposited by metal-organic chemical vapor deposition, by molecular beam epitaxy, by hydride vapor phase epitaxy, or by a combination thereof. The AlₓIn_{y}Ga_{1-x-y}N layer comprises an active layer that preferentially emits light when an electrical current is passed through it. The active layer can be a single quantum well, with a thickness between about 0.5 nm and about 40 nm. In another embodiment, the active layer is a multiple quantum well, or a double heterostructure, with a thickness between about 40 nm and about 500 nm. In one specific embodiment, the active layer comprises an In_{y}Ga_{1-y}N layer, where 0≦y≦1.

The invention provides packages and devices including at least one LED placed on a mounting member. In other embodiments, the starting materials can include polar gallium nitride containing materials and others, such as sapphire, aluminum nitride, silicon, silicon carbide, and other substrates. The present packages and devices are preferably combined with phosphors to discharge white light.

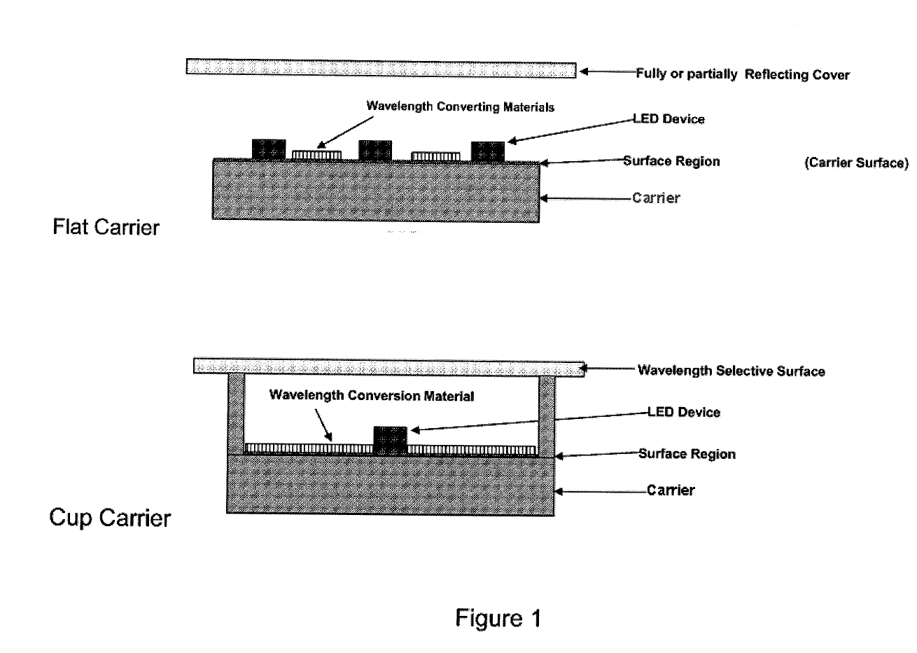

FIG. 1 is a diagram of a flat carrier packaged light emitting device 100 and recessed or cup packaged light emitting device 110. The invention provides a packaged light emitting device configured in a flat carrier package 100. As shown, the device has a mounting member with a surface region. The mounting member is made of a suitable material such a ceramics, semiconductors (e.g., silicon), metal (aluminum, Alloy 42 or copper), plastics, dielectrics, and the like. The substrate may be provided as a lead frame member, a carrier or other structure. These are collectively referred to as “substrate” in the drawings.

The mounting member, which holds the LED, can come in various shapes, sizes, and configurations. Usually the surface region of the mounting member is substantially flat, although there may be one or more slight variations the surface region, for example, the surface can be cupped or terraced, or a combinations of the flat and cupped shapes. Additionally, the surface region generally has a smooth surface, plating, or coating. Such plating or coating can be gold, silver, platinum, aluminum, dielectric with metal thereon, or other material suitable for bonding to an overlying semiconductor material.

Referring again to FIG. 1, the optical device has light emitting diodes overlying the surface region. The light emitting diode devices 103 can be any type of LED, but in the preferred embodiment are preferably fabricated on a semipolar or nonpolar GaN containing substrate, but can be fabricated on polar gallium and nitrogen containing material. Preferably, the LED emits polarized electromagnetic radiation 105. The light emitting device is coupled to a first potential, which is attached to the substrate, and a second potential 109, which is coupled to wire or lead 111 bonded to a light emitting diode.

The light emitting diode device can be a blue-emitting LED device and the substantially polarized emission is blue light from about 440 nanometers to about 490 nanometers wavelength. In specific embodiments, a {1-100} m-plane bulk substrate or a {10-1-1} semi-polar bulk substrate is used for the semipolar blue LED. The substrate has a flat surface, with a root-mean-square (RMS) roughness of about 0.1 nm, a threading dislocation density less than 5×10⁶ cm⁻², and a carrier concentration of about 1×10¹⁷ cm⁻³. Epitaxial layers are deposited on the substrate by metalorganic chemical vapor deposition (MOCVD) at atmospheric pressure. The ratio of the flow rate of the group V precursor (ammonia) to that of the group III precursor (trimethyl gallium, trimethyl indium, trimethyl aluminum) during growth is between about 3000 and about 12000. First, a contact layer of n-type (silicon-doped) GaN is deposited on the substrate, with a thickness of about 5 microns and a doping level of about 2×10¹⁸ cm⁻³. Next, an undoped InGaN/GaN multiple quantum well (MQW) is deposited as the active layer. The MQW superlattice has six periods, comprising alternating layers of 8 nm of InGaN and 37.5 nm of GaN as the barrier layers. Then, a 10 nm undoped AlGaN electron blocking layer is deposited. Finally, a p-type GaN contact layer is deposited, with a thickness of about 200 nm and a hole concentration of about 7×10¹⁷ cm⁻³. Indium tin oxide (ITO) is e-beam evaporated onto the p-type contact layer as the p-type contact and rapid-thermal-annealed. LED mesas, with a size of about 300×300 μm², are formed by photolithography and dry etching using a chlorine-based inductively-coupled plasma (ICP) technique. Ti/Al/Ni/Au is e-beam evaporated onto the exposed n-GaN layer to form the n-type contact, Ti/Au is e-beam evaporated onto a portion of the ITO layer to form a p-contact pad, and the wafer is diced into discrete LED dies. Electrical contacts are formed by conventional wire bonding.

In a specific embodiment, the optical device has a 100 micron or less thickness of material formed on an exposed portion of the surface region separate from the LEDs. The material includes wavelength conversion materials that convert electromagnetic radiation reflected off the wavelength selective reflector. Typically the material is excited by the LED emission and emits electromagnetic radiation of second wavelengths. In a preferred embodiment, the material emits substantially green, yellow, and or red light from an interaction with the blue light.

The entities preferably comprise phosphors or phosphor blends selected from (Y, Gd, Tb, Sc, Lu, La)₃(Al, Ga, In)₅O₁₂:Ce³⁺, SrGa₂S₄:Eu²⁺, SrS:Eu²⁺, and colloidal quantum dot thin films comprising CdTe, ZnS, ZnSe, ZnTe, CdSe, or CdTe. In other embodiments, the device includes a phosphor capable of emitting substantially red light. Such phosphor is selected from one or more of (Gd,Y,Lu,La)₂O₃:Eu³⁺, Bi³⁺; (Gd,Y,Lu,La)₂O₂S:Eu³⁺, Bi³⁺; (Gd,Y,Lu,La)VO₄:Eu³⁺, Bi³⁺; Y₂(O,S)₃: Eu⁺; Ca₁₋ₓMo_{1-y}Si_{y}O₄:, where 0.05≦x≦0.5, 0≦y≦0.1; (Li,Na,K)₅Eu(W,Mo)O₄; (Ca,Sr)S:Eu²⁺; SrY₂S₄:Eu²⁺; CaLa₂S₄:Ce³⁺; (Ca,Sr)S:Eu²⁺; 3.5MgO*0.5MgF₂*GeO₂:Mn⁴⁺ (MFG); (Ba,Sr,Ca)MgxP₂O₇:Eu²⁺, Mn²⁺; (Y,Lu)₂WO₆:Eu³⁺, Mo⁶⁺; (Ba,Sr,Ca)₃MgxSi₂O₈:Eu²⁺, Mn²⁺, wherein 1<x≦2; (RE_{1-y}Ce_{y})Mg₂₋ₓLiₓSi₃₋ₓPₓO₁₂, where RE is at least one of Sc, Lu, Gd, Y, and Tb, 0.0001<x<0.1 and 0.001<y<0.1; (Y, Gd, Lu, La)₂₋ₓEuₓW_{1-y}Mo_{y}O₆,where 0.5≦x.≦1.0, 0.01≦y≦1.0; (SrCa)₁₋ₓEuₓSi₅N₈, where 0.01≦x≦0.3; SrZnO₂:Sm⁺³; MₘOₙX wherein M is selected from the group of Sc, Y, a lanthanide, an alkali earth metal and mixtures thereof; X is a halogen; 1≦m≦3; and 1≦n≦4, and wherein the lanthanide doping level can range from 0.1 to 40% spectral weight; and Eu³⁺ activated phosphate or borate phosphors; and mixtures thereof.

Quantum dot materials comprise a family of semiconductor and rare earth doped oxide nanocrystals whose size and chemistry determine their luminescent characteristics. Typical chemistries for the semiconductor quantum dots include well known (ZnxCd1−x)Se[x=0 . . . 1], (Znx,Cd1−x)Se[x=0 . . . 1], Al(AsxP1−x)[x=0 . . . 1], (Znx,Cd1−x)Te[x=0 . . . 1], Ti(AsxP1−x)[x=0 . . . 1], In(AsxP1−x)[x=0 . . . 1], (AlxGa1−x)Sb[x=0 . . . 1], (Hgx,Cd1−x)Te[x=0 . . . 1] zincblende semiconductor crystal structures. Published examples of rare-earth doped oxide nanocrystals include Y2O3:Sm3+, (Y,Gd)2O3:Eu3+, Y2O3:Bi, Y2O3:Tb, Gd2SiO5:Ce, Y2SiO5:Ce, Lu2SiO5:Ce, Y3Al5)12:Ce but should not exclude other simple oxides or orthosilicates. Many of these materials are being actively investigated as suitable replacement for the Cd and Te containing materials which are considered toxic.

For purposes herein, when a phosphor has two or more dopant ions (i.e., those ions following the colon in the above phosphors), it means that the phosphor has at least one (but not necessarily all) of those dopant ions within the material. As understood by those skilled in the art, this notation means that the phosphor can include any or all of those specified ions as dopants in the formulation.

In another embodiment, the light emitting diode devices include at least a violet-emitting LED device capable of emitting electromagnetic radiation at a range from about 380 nanometers to about 440 nanometers and the entities are capable of emitting substantially white light. In a specific embodiment, a (1-100) m-plane bulk substrate is provided for the nonpolar violet LED. The substrate has a flat surface, with a root-mean-square (RMS) roughness of about 0.1 nm, a threading dislocation density less than 5×10⁶ cm⁻², and a carrier concentration of about 1×10¹⁷ cm⁻³. Epitaxial layers are deposited on the substrate by metalorganic chemical vapor deposition (MOCVD) at atmospheric pressure. The ratio of the flow rate of the group V precursor (ammonia) to that of the group III precursor (trimethyl gallium, trimethyl indium, trimethyl aluminum) during growth is between about 3000 and about 12000. First, a contact layer of n-type (silicon-doped) GaN is deposited on the substrate, with a thickness of about 5 microns and a doping level of about 2×10¹⁸ cm⁻³. Next, an undoped InGaN/GaN multiple quantum well (MQW) is deposited as the active layer. The MQW superlattice has six periods, comprising alternating layers of 16 nm of InGaN and 18 nm of GaN as the barrier layers. Next, a 10 nm undoped AlGaN electron blocking layer is deposited. Finally, a p-type GaN contact layer is deposited, with a thickness of about 160 nm and a hole concentration of about 7×10¹⁷ cm⁻³. Indium tin oxide (ITO) is e-beam evaporated onto the p-type contact layer as the p-type contact and rapid-thermal-annealed. LED mesas, with a size of about 300×300 μm2, are formed by photolithography and dry etching. Ti/Al/Ni/Au is e-beam evaporated onto the exposed n-GaN layer to form the n-type contact, Ti/Au is e-beam evaporated onto a portion of the ITO layer to form a contact pad, and the wafer is diced into discrete LED dies. Electrical contacts are formed by conventional wire bonding. Other colored LEDs may also be used or combined according to a specific embodiment. In a similar embodiment, the LED is fabricated on a polar bulk GaN orientation.

In a specific embodiment, the entities comprise a blend of phosphors capable of emitting substantially blue light, substantially green light, and substantially red light. As an example, the blue emitting phosphor can be selected from the group consisting of (Ba,Sr,Ca)₅(PO₄)₃(Cl,F,Br,OH):Eu²⁺, Mn²⁺; Sb³⁺,(Ba,Sr,Ca)MgAl₁₀O₁₇:Eu²⁺, Mn²⁺; (Ba,Sr,Ca)BPO₅:Eu²⁺, Mn²⁺; (Sr,Ca)₁₀(PO₄)₆*nB₂O₃:Eu²⁺; 2SrO*0.84P₂O₅*0.16B₂O₃:Eu²⁺; Sr₂Si₃O₈*2SrCl₂:Eu²⁺; (Ba,Sr,Ca)MgₓP₂O₇:Eu²⁺, Mn²⁺; Sr₄Al₁₄O₂₅:Eu²⁺ (SAE); BaAl₈O₁₃:Eu²⁺; and mixtures thereof. The green phosphor can be selected from the group consisting of (Ba,Sr,Ca)MgAl₁₀O₁₇:Eu²⁺, Mn²⁺ (BAMn); (Ba,Sr,Ca)Al₂O₄:Eu²⁺; (Y,Gd,Lu,Sc,La)BO₃:Ce³⁺,Tb³⁺; Ca₈Mg(SiO₄)₄Cl₂:Eu²⁺, Mn²⁺; (Ba,Sr,Ca)₂SiO₄:Eu²⁺; (Ba,Sr,Ca)₂(Mg,Zn)Si₂O₇:Eu²⁺; (Sr,Ca,Ba)(Al,Ga,ln)₂S₄:Eu²⁺; (Y,Gd,Tb,La,Sm,Pr,Lu)₃(Al,Ga)₅O₁₂:Ce³⁺; (Ca,Sr)₈(Mg,Zn)(SiO₄)₄C₁₂:Eu²⁺, Mn²⁺ (CASI); Na₂Gd₂B₂O₇:Ce³⁺, Tb³⁺; (Ba,Sr)₂(Ca,Mg,Zn)B₂O₆:K,Ce,Tb; and mixtures thereof. The red phosphor can be selected from the group consisting of (Gd,Y,Lu,La)₂O₃:Eu³⁺, Bi³⁺; (Gd,Y,Lu,La)₂O₂S:Eu³⁺, Bi³⁺; (Gd,Y,Lu,La)VO₄:Eu³⁺, Bi³⁺; Y₂(O,S)₃: Eu³⁺; Ca₁₋ₓMo_{1-y}Si_{y}O₄:, where 0.05≦x≦0.5, 0≦y≦0.1; (Li,Na,K)₅Eu(W,Mo)O₄; (Ca,Sr)S:Eu²⁺; SrY₂S₄:Eu²⁺; CaLa₂S₄:Ce³⁺; (Ca,Sr)S:Eu²⁺; 3.5MgO*0.5MgF₂*GeO₂:Mn⁴⁺ (MFG); (Ba,Sr,Ca)MgₓP₂O₇:Eu²⁺, Mn²⁺; (Y,Lu)₂WO₆:Eu³⁺, Mo⁶⁺; (Ba,Sr,Ca)₃MgₓSi₂O₈:Eu²⁺, Mn²⁺, wherein 1<x≦2; (RE_{1-y}Ce_{y})Mg₂₋ₓLiₓSi₃₋ₓPₓO₁₂, where RE is at least one of Sc, Lu, Gd, Y, and Tb, 0.0001<x<0.1 and 0.001<y<0.1; (Y, Gd, Lu, La)₂₋ₓEuₓW_{1-y}Mo_{y}O₆, where 0.5≦x≦1.0, 0.01≦y≦1.0; (SrCa)₁₋ₓEuₓSi₅N₈, where 0.01≦x≦0.3; SrZnO₂:Sm⁺³; MₘOₙX, wherein M is selected from the group of Sc, Y, a lanthanide, an alkali earth metal and mixtures thereof; X is a halogen; 1≦m≦3; and 1≦n≦4, and wherein the lanthanide doping level can range from 0.1 to 40% spectral weight; and Eu³⁺ activated phosphate or borate phosphors; and mixtures thereof.

It would be recognized that other “energy-converting luminescent materials,” which include phosphors, semiconductors, semiconductor nanoparticles (“quantum dots”), organic luminescent materials, and the like, and combinations of them, can also be used. The energy converting luminescent materials can generally be a wavelength converting material and/or materials.

In one embodiment, the packaged device has a flat carrier configuration and includes an enclosure which includes a flat region that is wavelength selective. The enclosure can be made of a suitable material such as an optically transparent plastic, glass, or other material. The enclosure has a suitable shape 119, which can be annular, circular, egg-shaped, trapezoidal, or other shape. As shown referring to the cup carrier configuration, the packaged device is provided within a terraced or cup carrier. Depending upon the embodiment, the enclosure with suitable shape and material is configured to facilitate and even optimize transmission of electromagnetic radiation reflected from internal regions of the package. The wavelength selective material can be a filter device applied as a coating to a surface region of the enclosure. In a preferred embodiment, the wavelength selective surface is a transparent material such as distributed Bragg Reflector (DBR) stack, a diffraction grating, a particle layer tuned to scatter selective wavelengths, a photonic crystal structure, a nanoparticle layer tuned for plasmon resonance enhancement at certain wavelengths, or a dichroic filter, or other approach.

The wavelength conversion material is usually within about one hundred microns of a thermal sink which is a surface region having thermal conductivity of greater than about 15, 100, 200, or even 300 Watt/m-Kelvin. In a specific embodiment, the wavelength conversion material has an average particle-to-particle distance of about less than about 2 times the average particle size of the wavelength conversion material, but it can be as much as 3 times, 5 times, or even 10 times the average particle size of the wavelength conversion material. Alternatively the wavelength conversion material can be provided as a filter device.

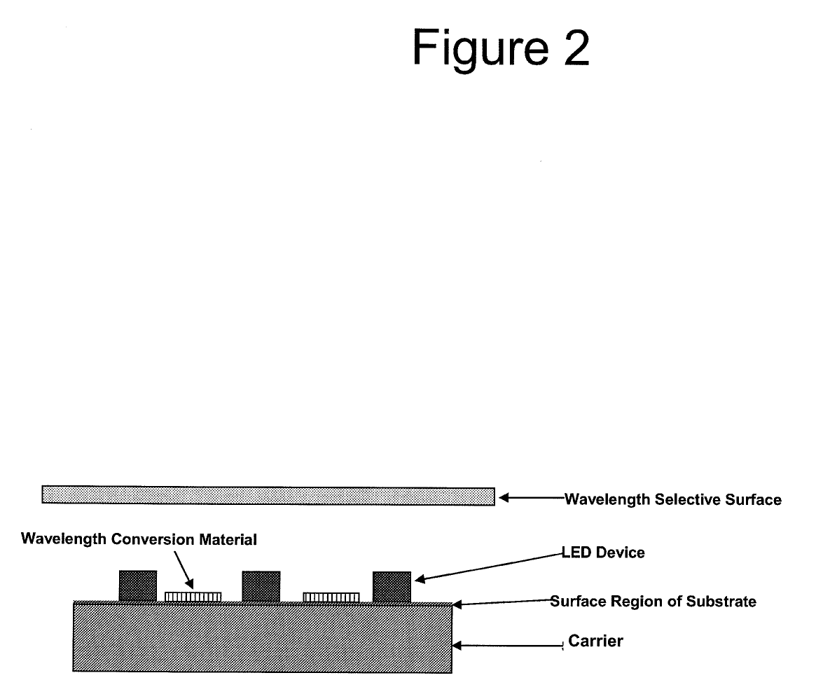

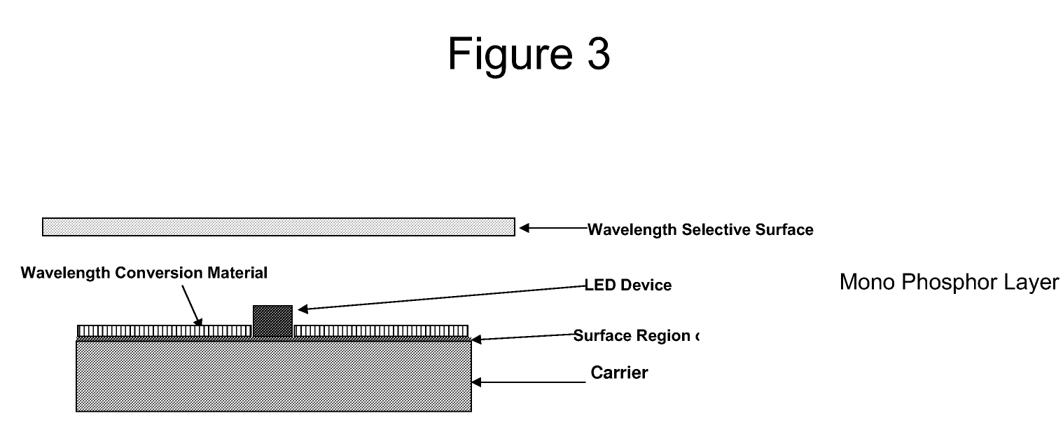

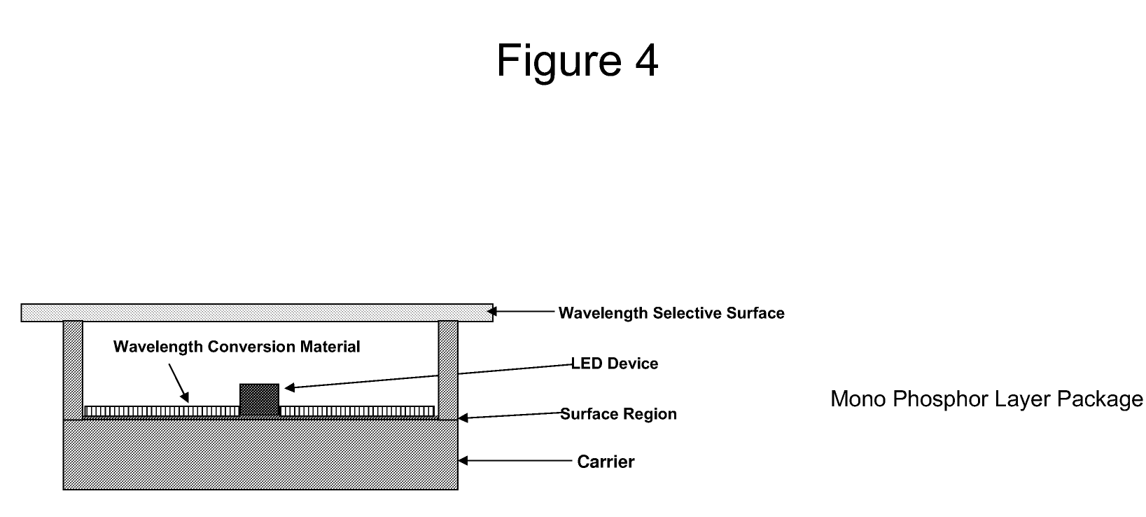

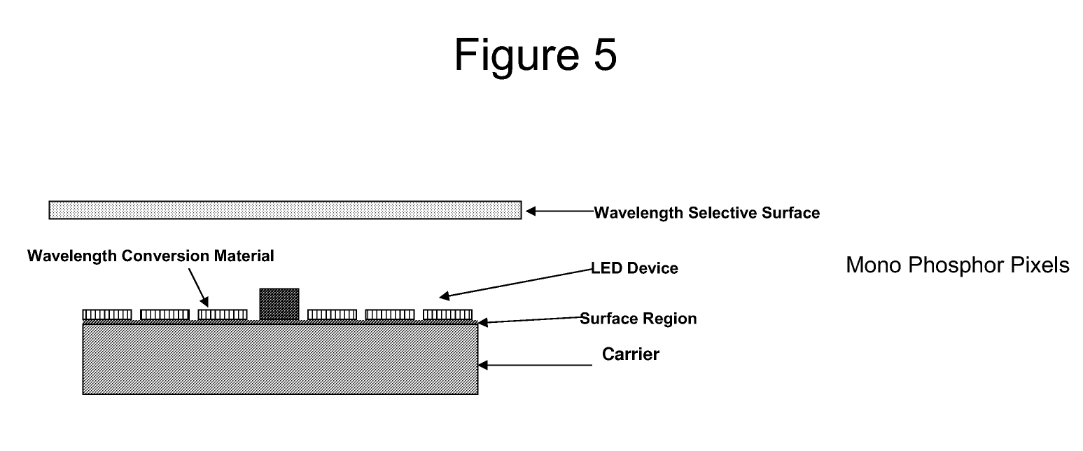

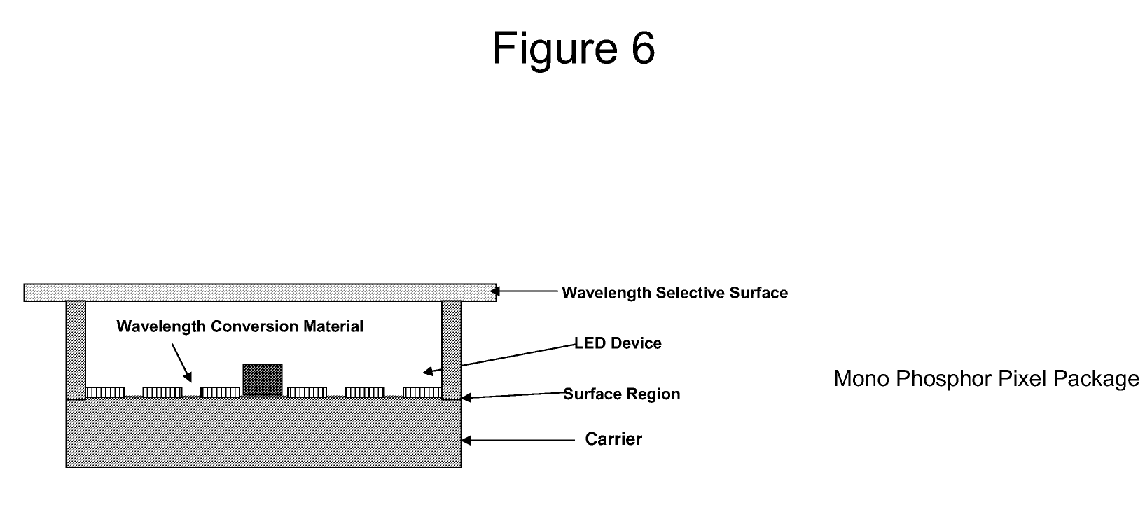

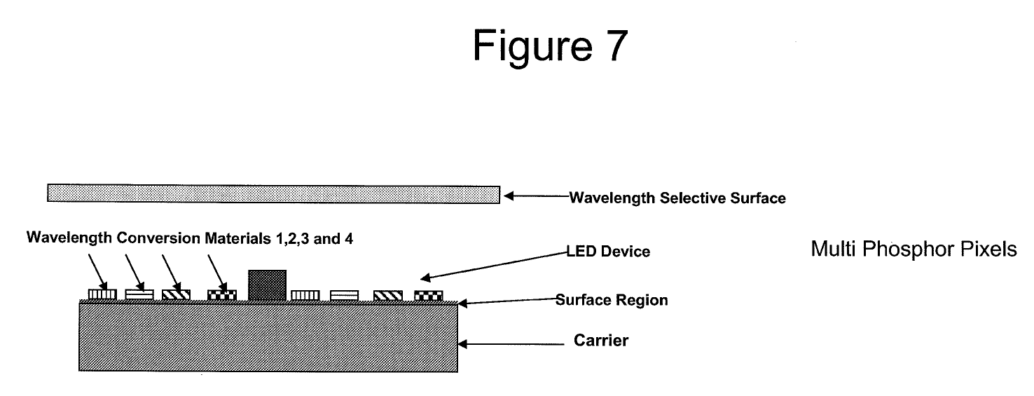

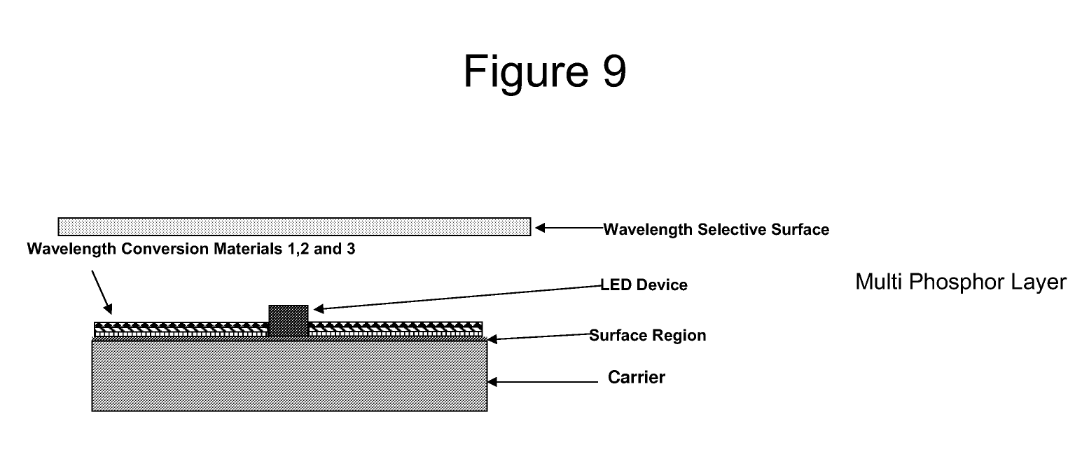

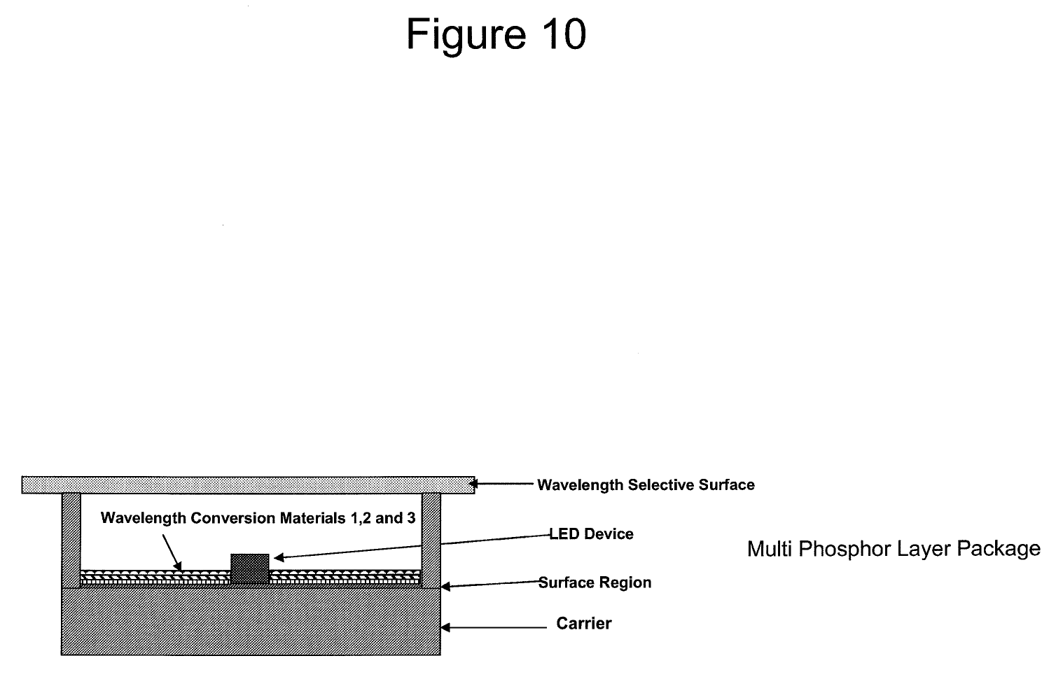

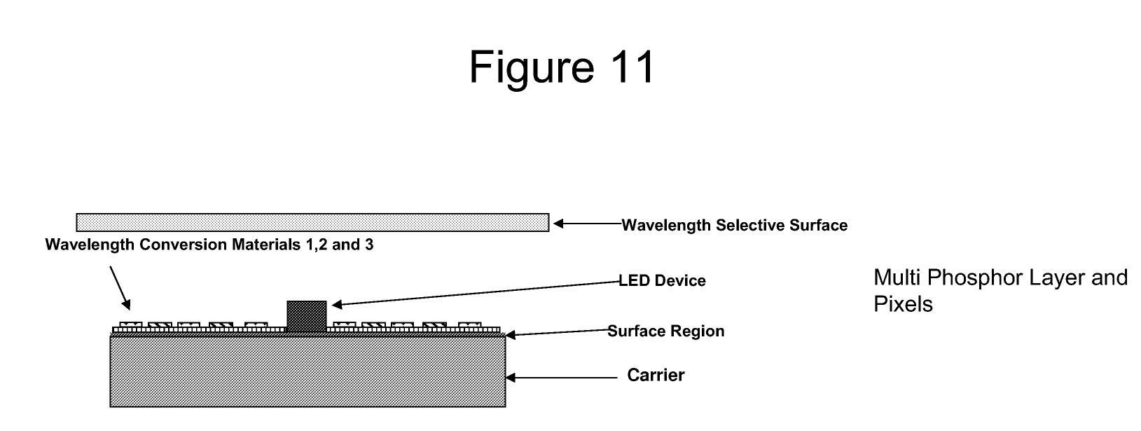

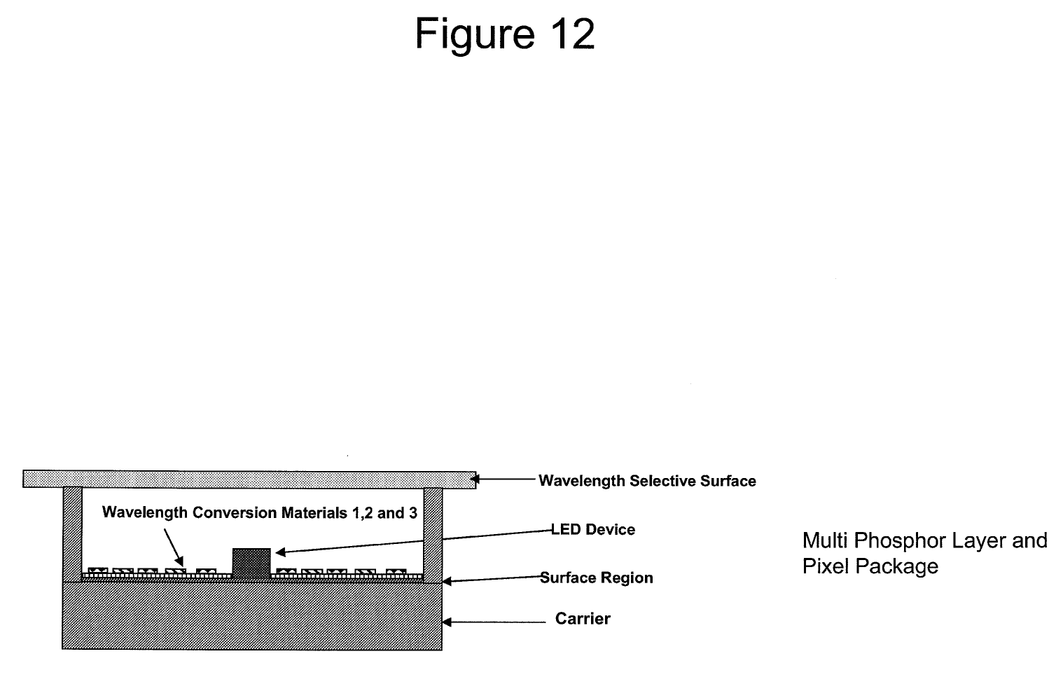

FIGS. 2 through 12 are diagrams of a packaged light emitting devices with reflection mode configurations. The enclosure has an interior region and an exterior region with a volume defined within the interior region. The volume is open and filled with a transparent materials such as silicone, or an inert gas or air to provide an optical path between the LED device or devices and the surface region. In a preferred embodiment, the optical path includes a path from the wavelength selective material to the wavelength conversion material, then back through the wavelength conversion material. In a specific embodiment, the enclosure also has a thickness and fits around a base region of the carrier.

Typically the entities are suspended in a suitable medium. An example of such a medium can be a silicone, glass, spin on glass, plastic, polymer, which is doped, metal, or semiconductor material, including layered materials, and/or composites, among others. Depending upon the embodiment, the medium including polymers begins as a fluidic state, which fills an interior region of the enclosure, and can fill and seal the LED device or devices. The medium is then cured and achieves a substantially stable state. The medium is preferably optically transparent, but can also be selectively transparent. In addition, the medium, once cured, is usually substantially inert. In a preferred embodiment, the medium has a low absorption capability to allow a substantial portion of the electromagnetic radiation generated by the LED device to traverse through the medium and be provided through the enclosure at desired wavelengths. In other embodiments, the medium can be doped or treated to selectively filter, disperse, or influence the selected wavelengths of light. As an example, the medium can be treated with metals, metal oxides, dielectrics, or semiconductor materials, and/or combinations of these materials.

The LED device can be configured in a variety of packages such as cylindrical, surface mount, power, lamp, flip-chip, star, array, strip, or geometries that rely on lenses (silicone, glass) or sub-mounts (ceramic, silicon, metal, composite). Alternatively, the package can be any variations of these packages.

In other embodiments, the packaged device can include other types of optical and/or electronic devices such as an OLED, a laser, a nanoparticle optical device, etc. If desired, the optical device can include an integrated circuit, a sensor, a micro-machined electronic mechanical system, or other device. The packaged device can be coupled to a rectifier to provide a power supply. The rectifier can be coupled to a suitable base, such as an Edison screw such as E27 or E14, bi-pin base such as MR16 or GU5.3, or a bayonet mount such as GU10. In other embodiments, the rectifier can be spatially separated from the packaged device.

The ultimate pixel resolution limit on a screen made of phosphors particles is the phosphor particle sizes themselves. By producing a phosphor layer whose thickness is on the scale of the particle diameter, effective ‘natural pixelation’ is produced, wherein each grain becomes a pixel. That is, the colored pixel is defined by a single phosphor particle. The inventors have determined that a properly designed recycling cavity (e.g., selective reflective member) can enable extended absorption path lengths thus minimizing required phosphor quantities to produce proper final colors, even to such a phosphor ‘mono-layer’ or sub-mono-layer. Single or multi particle screens of this type would improve thermal performance, package optical efficiency, and overall performance of the LED device. Numerous extensions of the concept can be applied to mixed, remote, layered plate-like configurations of phosphors.

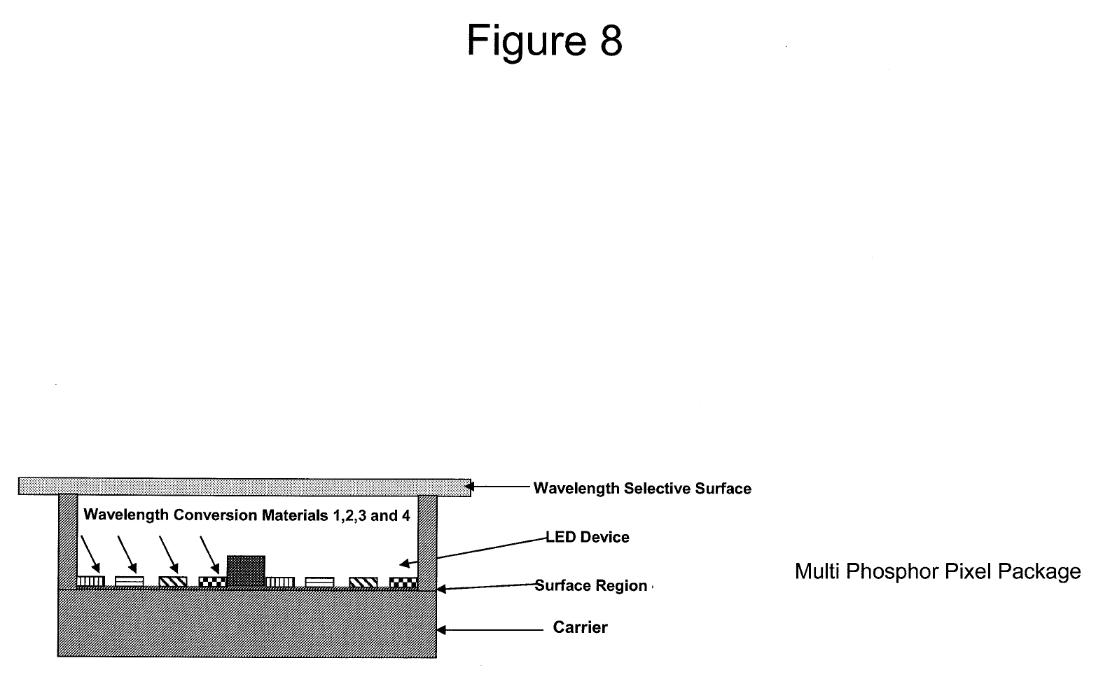

FIG. 8B shows an embodiment of the invention employing this concept. In this case the overall thickness of the reflection mode phosphor layer is on the order of the average grain height. The selected packing density of the phosphor can even allow gaps between grains, and achieve high conversion efficiency provided the surface upon which the grains lie is sufficiently reflective. Of course, multiple phosphors can be included in the reflection mode layer, for example red, green, and/or blue emitting phosphors for white-emitting LEDs. Benefits include optimum thermal configuration for particles (direct or near direct attach to substrate), minimizing crosstalk between phosphor particles thus minimizing cross absorption events, minimum use of expensive phosphor materials, minimum processing steps to produce an n-color screen, and minimization of far-field color separation.

Methods to apply the thin phosphor layer include, but are not limited to, spray coating/electrostatic powder coating, ultrasonic spray coating with baffle electrode in the path of the powders for charging the powders, single layer particle self assembly, dip pen lithography, mono layer electrophoretic deposition, sedimentation, phototacky application with dry dusting, electrostatic pickup with tacky attach, dip coating, etc.

Prior art (for example, Krames et al. in U.S. Pat. No. 7,026,66) shows a reduction in phosphor conversion efficiency for more than 30% direct emission from the primary LEDs. Reflection mode devices such as described here, however, improve in efficiency as the direct emission from the LEDs to the reflector is increased, since phosphor particles are not present to back-scatter light into the LED devices, which can then be lost. This is a central advantage of the reflection mode concept.

Johnson teaches (J.Opt.Soc.Am 42,978,1952) in the phosphor handbook (Shionoya and Yen, 16,787, 1999) that there exists a relationship between fluorescent brightness and number of phosphor particle layers. This is shown to be ˜5 particle layers based on halophosphate powder modeling. Brightness steadily drifts down as the number of particle layers increases to 10 layers (30% loss from 4 to 10 layers). Given typical particle sizes in LED based applications as 15-20 um, and an estimated peak fluorescence at 5 layers, it is desirable to have the maximum thickness of the wavelength conversion material at less than or equal to ˜100 um.

The reflection mode geometry, which is partly defined by the requirement that 30% of the emitted chip light must first strike the wavelength selective surface prior to striking the phosphor conversion material, eliminates highly scattering media from around the vicinity of the emitting chips and in the volume between the chips and the wavelength selective surface. This reduces backscatter losses within the chip as well as package level scattering losses, resulting in a more efficient optical design. In addition, the generation of wavelength converted light occurs predominately at the top surface of the wavelength conversion material, allowing this created light the least impeding optical path to exit from the package. By ensuring that the wavelength conversion material is placed on the surface region of the mounting member, the wavelength conversion material is provided with the optimum thermal path for heat dissipation, allowing the wavelength conversion material to operate at reduced temperature and higher conversion efficiency than designs where the wavelength conversion material does not have an adequate thermal path to operate at the lowest possible temperatures. By limiting the thickness of the wavelength conversion material layer to 100 um or less, the thermal path is not compromised by the thickness of the wavelength conversion material itself.

In tests, the inventors found that very thin layers of phosphors are all that are required if the recycling effect is strong enough. In fact, even less than a “monolayer” of phosphor material can result in high conversion. This gives the benefits of a) reduced amount of phosphor material required, b) provision of thinner layer which is better for heat sinking, and c) a ‘natural pixelation’ resulting in less cascading down-conversion events (i.e., where violet pumps blue pumps green pumps red).

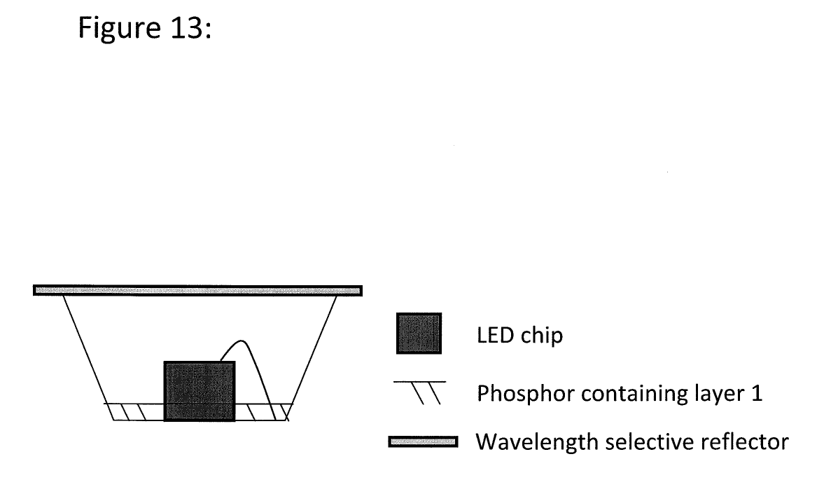

FIGS. 13 through 15 are simplified diagrams of alternative packaged light emitting devices using reflection mode configurations according to embodiments of the invention. Referring to FIG. 13, a mixed reflection mode optical device is illustrated. Phosphors are deposited on the base and/or surrounding walls of the package to form a wavelength conversion layer(s). In a specific embodiment, the LED emitted light is directed onto the surface of the wavelength conversion layer and the converted phosphor light is emitted directly out of the packaged LED. The device eliminates wavelength conversion materials, including particles from an exit path of the generated light, thus improving light output and package extraction. Additionally, locating the phosphor particles on the package surface provides at least an improved path for transferring heat generated on the particles (Stokes loss and non-unity Quantum efficiency). The device preferably includes phosphor particles on a reflective surface, e.g., reproducible color generation in LEDs, pixelation, and efficient heat dissipation. The reflective surface may includes silver, aluminum, or other combinations, layered, and/or polished materials.

In a deposition process, phosphor particles, as described elsewhere herein, are deposited onto a substrate. Phosphor particles may have a particle size distribution between about 0.1 micron and about 500 microns, or between about 5 microns and about 50 microns. In some embodiments, the particle size distribution of phosphor particles is monomodal, with a peak at an effective diameter between about 0.5 microns and about 400 microns. In other embodiments, the particle size distribution of phosphor particles is bimodal, with local peaks at two diameters, trimodal, with local peaks at three diameters, or multimodal, with local peaks at four or more effective diameters.

The package or mounting member may comprise a metal, a ceramic, a glass, a single crystal wafer, or the like. The mounting member may have a reflectivity greater than 50%, 60%, 70%, 80%, 90%, 95%, 98%, or even 99%, at wavelengths between about 380 nanometers and about 800 nanometers. In one specific embodiment, the mounting member comprises silver or other suitable materials. In some embodiments, the phosphor particles are mixed with a liquid, e.g. water, to form a slurry. In other embodiments, the liquid comprises an organic liquid, such as ethanol, isopropanol, methanol, acetone, ether, hexane, or the like. In one embodiment, the liquid is pressurized carbon dioxide.

In some embodiments, the phosphor particles in the form of a slurry are deposited onto substrate, e.g. by being sprayed, ink jet printed, silk-screen-printed, and then the liquid allowed to evaporate. In other embodiments, the phosphor particles in a slurry settle onto substrate by sedimentation, by centrifugation, by electrophoresis, or the like. In some embodiments, phosphor particles in excess of a monolayer are removed by washing.

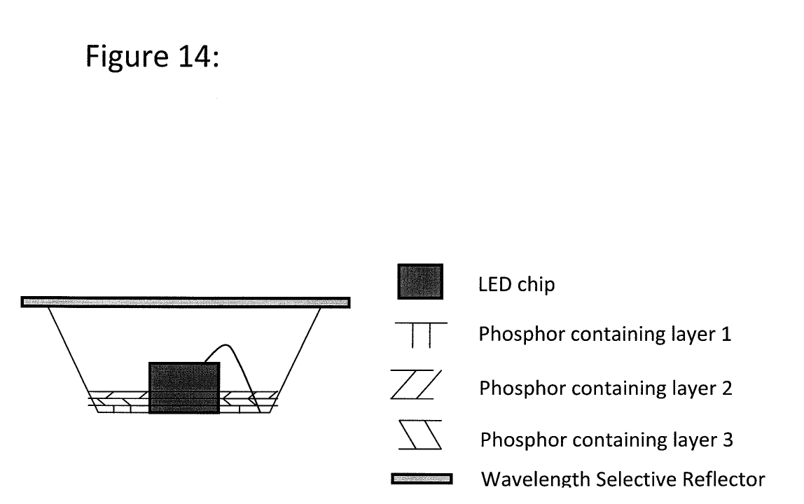

Referring now to FIG. 14, the invention provides a layered wavelength conversion material. As shown is an optical device, e.g., packaged LED having a mounting member with a surface region and LED devices over portions of the surface region. The device also includes exposed portions of the surface region. A first wavelength conversion material is disposed over some of the exposed portions and a second wavelength conversion material is disposed over portions of the first wavelength conversion material. A wavelength selective surface blocks substantially direct emission of the LED devices and transmits selected wavelengths of reflected emission caused by interaction with the wavelength conversion material. Preferably, layering of wavelength conversion material further reduces phosphor-phosphor absorption/re-emission processes which lead to lowered conversion efficiencies.

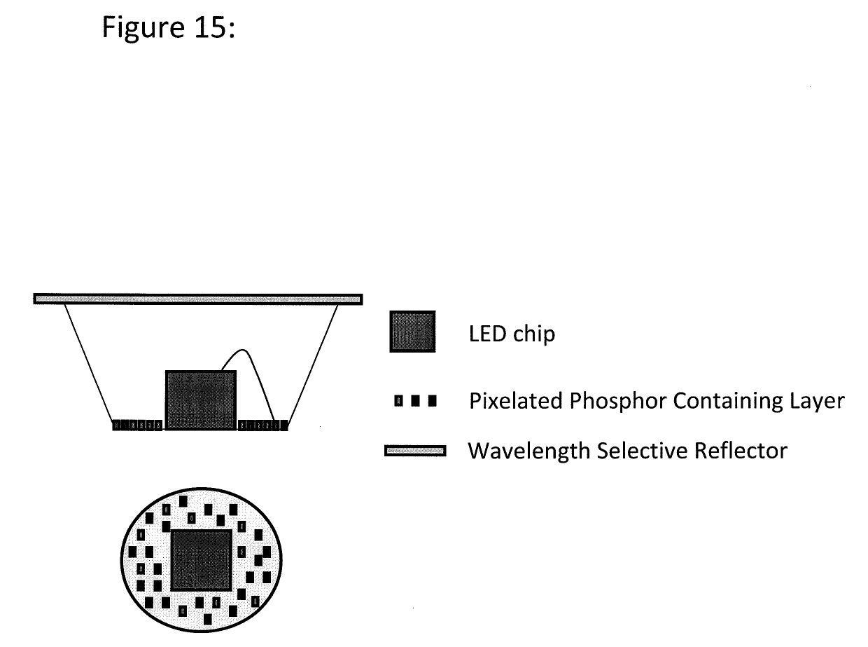

Referring now to FIG. 15, a pixelated wavelength conversion material is shown. The device has a mounting member with a surface region on which LED devices are disposed. Second portions of the surface region have wavelength conversion materials configured in a pixelated structure. The pixelated phosphor structure is employed for the reflection mode device. To increase interaction with LED emitted light, a reflector covering the top of the package, redirecting LED light downward toward the phosphor layer can be employed. Preferably, the pixilated structure includes advantages of the previous embodiments, as well as adding reduced phosphor interaction and areal color control.

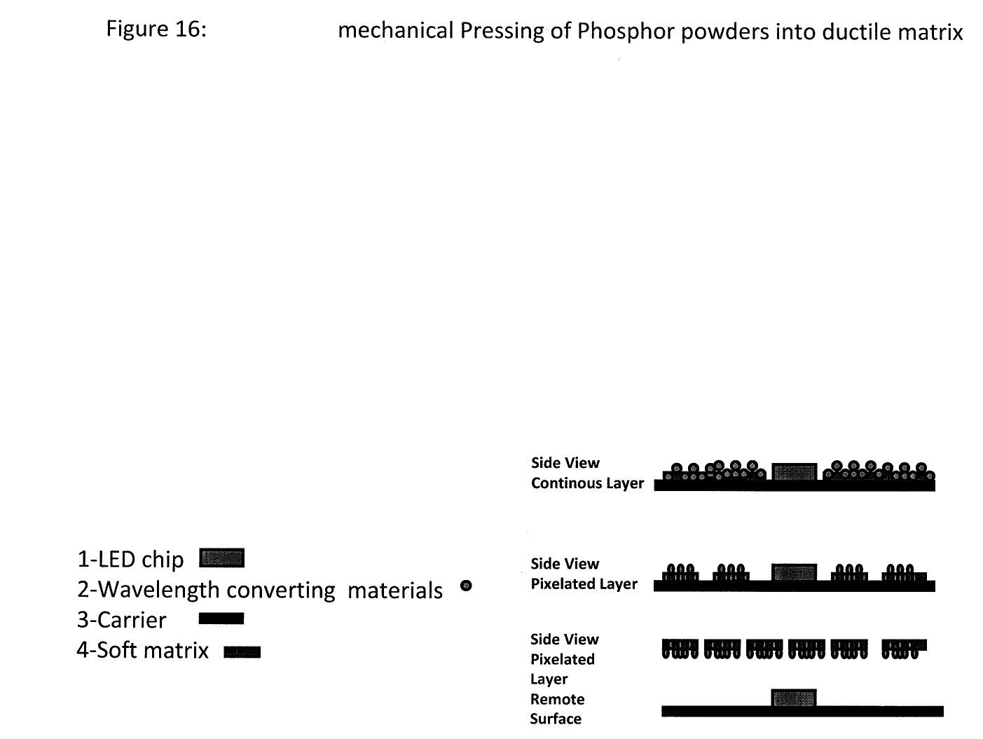

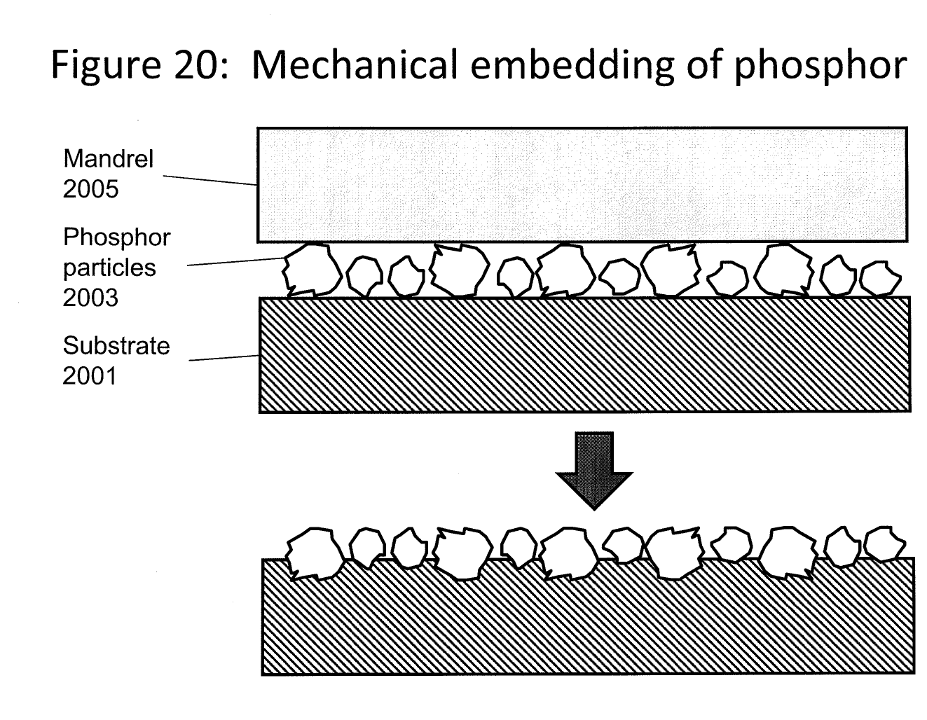

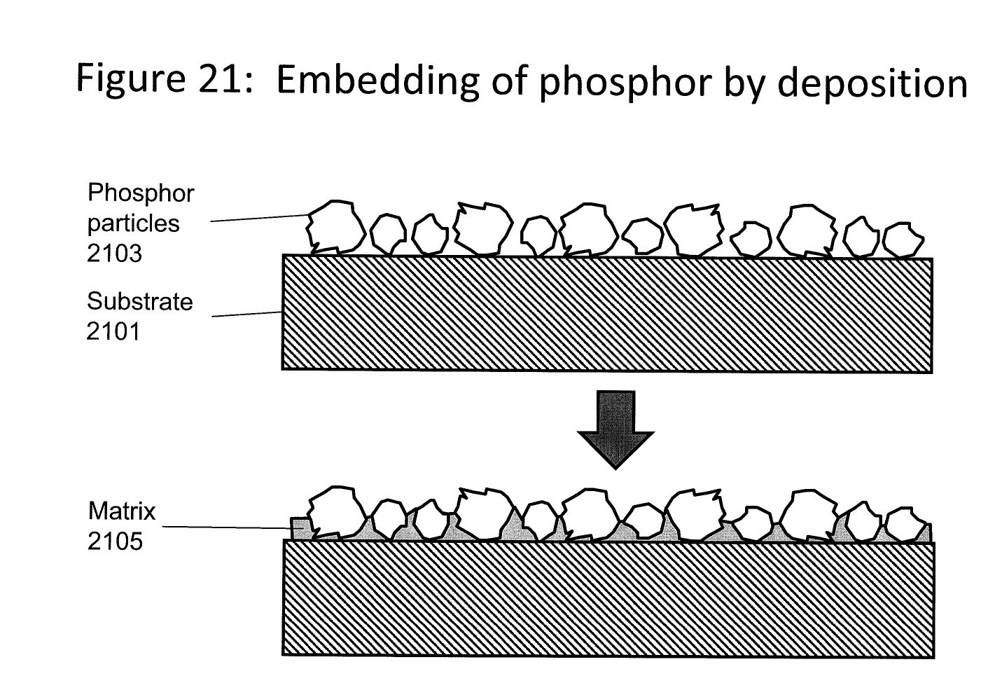

FIGS. 16 through 22 are diagrams of methods for applying wavelength conversion materials. As shown in FIG. 16, phosphor particles are embedded into a surface region of the substrate by mechanical means, e.g., mandrel or like. The mandrel, is usually a hard material, such as cemented tungsten carbide, silicon carbide, aluminum nitride, alumina, cubic boron nitride, diamond, or steel. The mandrel may alternatively comprise a relatively soft material, such as PTFE or PFA Teflon (registered trademark of the DuPont Company). If the mandrel has phosphor particles embedded in its surface, the mandrel may be pressed against the substrate with phosphor particles sandwiched in between. In a specific embodiment, the contact pressure between the mandrel and the substrate is between about 10⁵ Pascal and about 10⁸ Pascal, and the substrate is in an annealed condition. Deformation of its surface and embedding of phosphor particles can then take place with a minimum of contact pressure.

In other embodiments, the phosphor particles are embedded in a reflective matrix on the substrate by deposition. The reflective matrix can comprise silver or other suitable material, which may be ductile. The deposition process can be carried out by electroless deposition, and the substrate treated with an activating solution or slurry prior to deposition of the phosphor particles. In a specific embodiment, the activating solution or slurry includes at least one of SnCl₂, SnCl₄, Sn⁺², Sn⁺⁴, colloidal Sn (tin), Pd (palladium), Pt (platinum), or Ag (silver). The phosphor-covered can also be plated in an electroless plating bath with a plating solution such as at least one of silver ions, nitrate ions, cyanide ions, tartrate ions, ammonia, alkali metal ions, carbonate ions, and hydroxide ions. A reducing agent of dimethylamine borane (DMAB), potassium boron hydride, formaldehyde, hypophosphate, hydrazine, thiosulfate, sulfite, a sugar, or a polyhydric alcohol, can also be added to the solution.

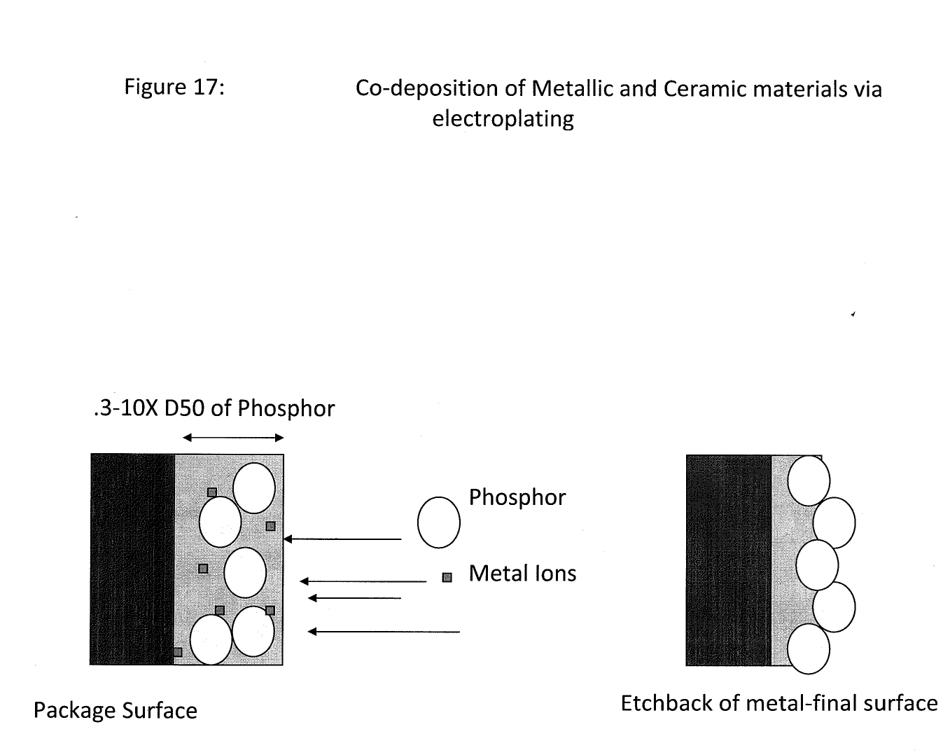

In another specific embodiment, the deposition process for the matrix comprises electrolytic deposition or electroplating as shown in FIG. 17. The phosphor-covered substrate is placed in an electroplating bath which includes at least one of silver ions, cyanide ions, nitrate ions, ammonia, phosphate ions, alkali metal ions, and hydroxide ions. The substrate is placed in electrical contact with the negative pole of a direct-current source, while the positive pole of the direct-current source is connected to silver electrodes placed in the electroplating bath and proximate to the substrate. The voltage of the direct-current source produces a current density between about 0.01 milliamperes per square centimeter and about 1 ampere per square centimeter, or between about 1 milliampere per square centimeter and about 0.1 ampere per square centimeter.

In other embodiments, after the matrix deposition process, the substrate/phosphor particle/matrix composite is subjected to an etching process to remove excess matrix material present on the outermost portion of the phosphor particles. The etching process comprises a wet process with an etching solution. The etching solution can be use nitric acid HNO₃, ferric nitrate Fe(NO3)3, Ce(NH₄)₂(NO₃)₆, NH₄NO₃, or KI/I₂. After the etch, a cleaning and/or rinsing step is performed, followed by drying.

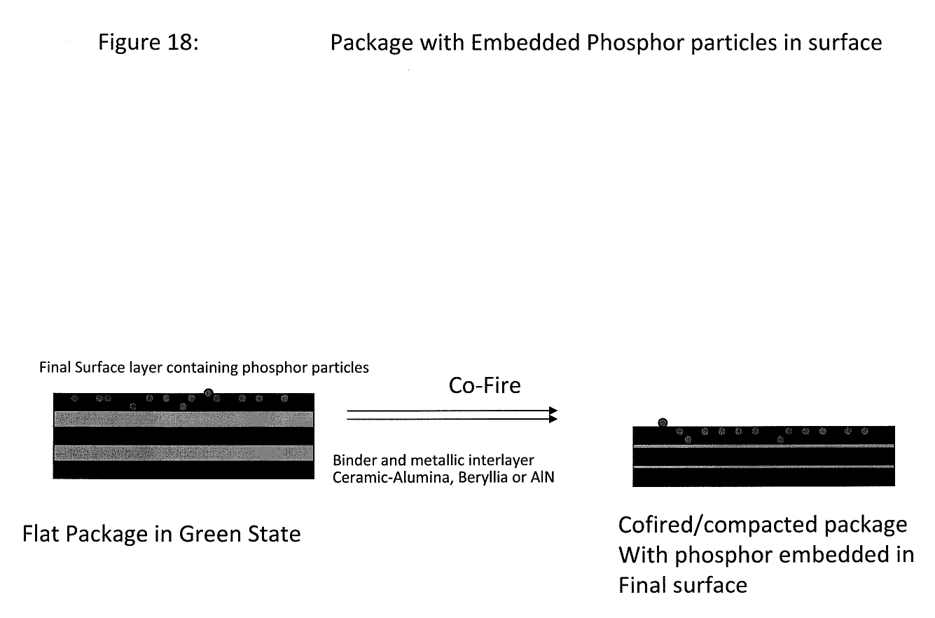

Referring now to FIG. 18, the invention also provides wavelength conversion materials embedded in the package itself As an example, starting with a standard green tape ceramic or screen printing process for LED packages, incorporate phosphor particles into the final tape layers and co-fire. Preferably, the method produces a luminescent package layer that is mechanically stable with thermal path through the package itself.

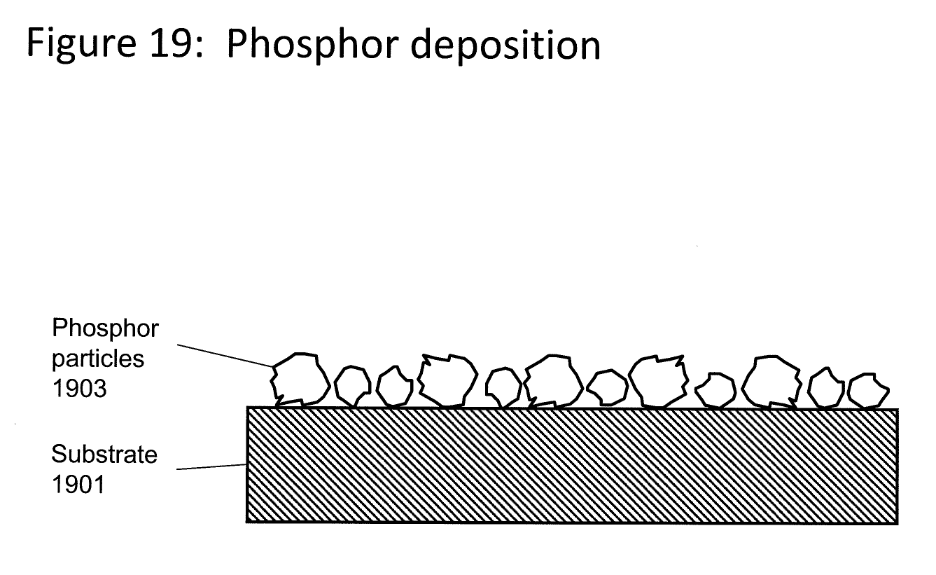

The method includes processes to form phosphor particles overlying the reflective surfaces. In a first, deposition step, phosphor particles 1903 are deposited onto a mounting member 1901, as shown in FIG. 19. Phosphor particles 1903 may comprise any of those listed herein, as well as other combinations. Phosphor particles 1903 preferably have a particle size distribution between about 0.1 micron and about 500 microns, or between about 5 microns and about 50 microns. In some embodiments, the particle size distribution of phosphor particles 103 is monomodal, with a peak at an effective diameter between about 0.5 microns and about 400 microns. In other embodiments, the particle size distribution of phosphor particles 103 is bimodal, with local peaks at two diameters, trimodal, with local peaks at three diameters, or multimodal, with local peaks at four or more effective diameters.

Mounting member 1901 may comprise a metal, a ceramic, a glass, a single crystal wafer, or the like. Mounting member 1901 may have a reflectivity greater than 50%, 60%, 70%, 80%, 90%, 95%, 98%, or even 99%, at wavelengths between about 390 nanometers and about 800 nanometers. The phosphor particles 1903 can be applied to the substrate using the same processes as described above.

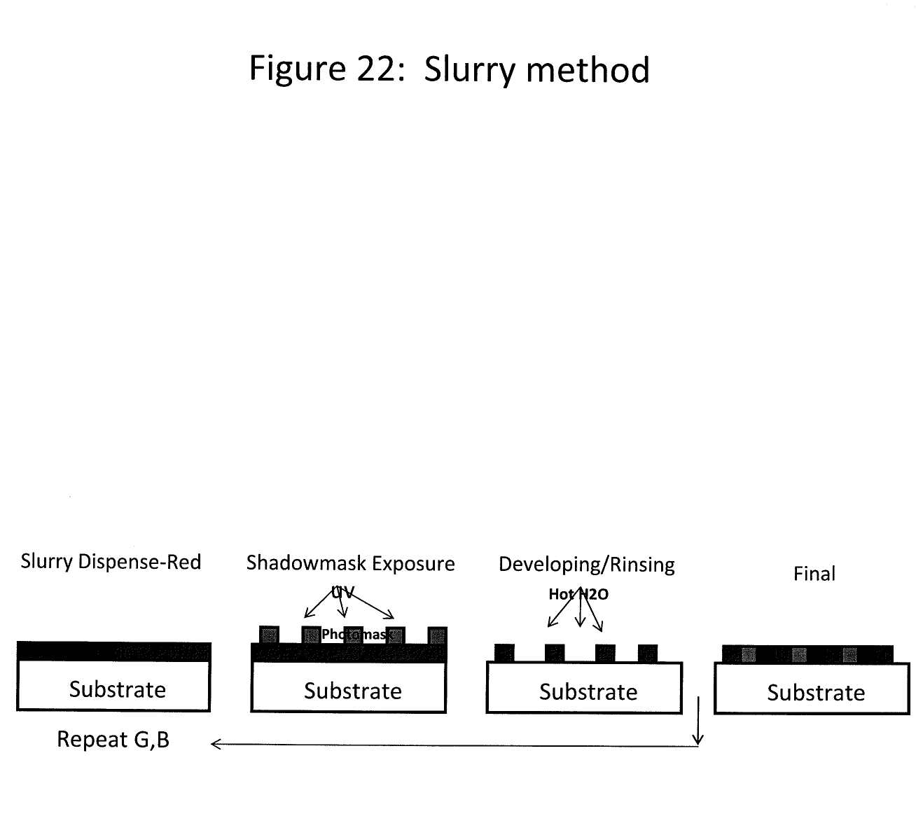

Referring now to FIG. 22, process steps include (1) slurry dispense; (2) shadowmask exposure; (3) developing; (4) repetition (RGB); (5) and others. In a specific embodiment, the single colored R, G, or B phosphors are suspended in solution (typically PVA) with sensitized binder (typically an aqueous dichromate). The slurry may be flood dispensed on a surface, as shown. Once proper thickness is established, the slurry is dried and photo-exposed (UV) thru a shadow-mask which defines the exposure area (pixels). Developing may include a hot water spray to wash off unexposed areas followed by repetition of any one or more steps for subsequent colors. Again, there can be other variations, modifications, and alternatives.

In preferred embodiments of the invention, a significantly higher average thermal conductivity is expected, due to a much smaller average phosphor particle-to-particle distance, and additionally, in some embodiments, from the use of a matrix with a thermal conductivity which is significantly higher than a typical silicone/epoxy. The resulting device will have an average bulk thermal conductivity of the wavelength conversion materials and the matrices, surfaces or interfaces to which they are coupled that is greater than 5 W/m-K, 10 W/m-K, 20 W/m-K, 50 W/m-K or even greater than 100 W/m-K.

This invention can provide a package with a desired average steady-state temperature of phosphor particles. That is, the average temperature of phosphor particles in a phosphor+silicone/epoxy matrix in a conventional LED application is estimated to be in excess of 150 C, due to the poor heat dissipation resulting from the low thermal conductivity of the matrix. A significantly lower average steady-state temperature is expected, due to higher in phosphor particle-to-particle head conduction/dissipation, and additionally, in some embodiments, due to the use of a matrix with a thermal conductivity which is significantly higher than a typical silicone/epoxy. There are benefits from a lower average steady-state temperature of phosphor particles—higher phosphor conversion efficiencies at lower temperatures, as well as reduced/no degradation of the matrix from elevated temperatures (silicone/epoxy degradation at temperatures in excess of 150 C is a possible failure mode).

The average steady-state temperature of the wavelength conversion particles of the wavelength conversion materials preferably is less than 150 C during operation, but can be less than 125 C, 100 C, 75 C, 50 C, or even within 25 C or 50 C of the average temperature of the heat-sink in the device package during operation.

Additionally, the present packaged device can be provided in a variety of applications. In a preferred embodiment, the application is general lighting, which includes buildings for offices, housing, outdoor lighting, stadium lighting, and others. Alternatively, the applications can be for display, such as those used for computing applications, televisions, flat panels, micro-displays, and others. Still further, the applications can include automotive, gaming, and others.

In a specific embodiment, the present devices are configured to achieve spatial uniformity. That is, diffusers can be added to the encapsulant to achieve spatial uniformity. Depending upon the embodiment, the diffusers can include TiO₂, CaF₂, SiO₂, CaCO₃, BaSO₄, and others, which are optically transparent and have a different index than the encapsulant causing the light to reflect, refract, and scatter to make the far field pattern more uniform.

As used herein, the term GaN substrate is associated with Group III-nitride based materials including GaN, InGaN, AlGaN, or other Group III containing alloys or compositions that are used as starting materials. Such starting materials include polar GaN substrates (i.e., substrate where the largest area surface is nominally an (h k l) plane wherein h=k=0, and 1 is non-zero), non-polar GaN substrates (i.e., substrate material where the largest area surface is oriented at an angle ranging from about 80-100 degrees from the polar orientation described above towards an (h k l) plane wherein l=0, and at least one of h and k is non-zero) or semi-polar GaN substrates (i.e., substrate material where the largest area surface is oriented at an angle ranging from about +0.1 to 80 degrees or 110-179.9 degrees from the polar orientation described above towards an (h k 1) plane wherein l=0, and at least one of h and k is non-zero).

In one or more specific embodiments, wavelength conversion materials can be ceramic or semiconductor particle phosphors, ceramic or semiconductor plate phosphors, organic or inorganic downconverters, upconverters (anti-stokes), nanoparticles and other materials which provide wavelength conversion. Some examples are listed below
(Sr,Ca)10(PO4)6*DB2O3:Eu2+ (wherein 0<n̂l)
(Ba,Sr,Ca)5(PO4)3(Cl,F,Br,OH):Eu2+,Mn2+
(Ba,Sr,Ca)BPO5:Eu2+,Mn2+
Sr2Si3O8*2SrCl2:Eu2+
(Ca,Sr,Ba)3MgSi2O8:Eu2+, Mn2+
BaAl8O13:Eu2+
2SrO*0.84P2O5*0.16B2O3:Eu2+
(Ba,Sr,Ca)MgAl10O17:Eu2+,Mn2+
K2SiF6:Mn4+
(Ba,Sr,Ca)Al2O4:Eu2+
(Y,Gd,Lu,Sc,La)BO3:Ce3+,Tb3+
(Ba,Sr,Ca)2(Mg,Zn)Si2O7:Eu2+
(Mg,Ca,Sr, Ba,Zn)2Si1_xO4_{—}2x:Eu2+ (wherein 0<x=0.2)
(Sr,Ca,Ba)(Al,Ga,m)2S4:Eu2+
(Lu,Sc,Y,Tb)2_u_vCevCa1+uLiwMg2_wPw(Si,Ge)3_w012_u/2 where —O.SSû1; 0<v£Q.1; and OSŵO.2
(Ca,Sr)8(Mg,Zn)(SiO4)4Cl2:Eu2+,Mn2+
Na2Gd2B2O7:Ce3+,Tb3+
(Sr,Ca,Ba,Mg,Zn)2P2O7:Eu2+,Mn2+
(Gd,Y,Lu,La)2O3:Eu3+,Bi3+
(Gd,Y,Lu,La)2O2S:Eu3+,Bi3+
(Gd,Y,Lu,La)VO4:Eu3+,Bi3+
(Ca,Sr)S:Eu2+,Ce3+
(Y,Gd,Tb,La,Sm,Pr,Lu)3(Sc,Al,Ga)5_nO12_{—}3/2n:Ce3+ (wherein 0̂0̂0.5)
ZnS:Cu+,Cl˜
ZnS:Cu+,Al3+
ZnS:Ag+,Al3+
SrY2S4:Eu2+
CaLa2S4:Ce3+
(Ba,Sr,Ca)MgP2O7:Eu2+,Mn2+
(Y,Lu)2WO6:Eu3+,Mo6+
CaWO4
(Y,Gd,La)2O2S:Eu3+
(Y,Gd,La)2O3:Eu3+
(Ca,Mg)xSyO:Ce
(Ba,Sr,Ca)nSinNn:Eu2+ (wherein 2n+4=3n)
Ca3(SiO4)Cl2:Eu2+
ZnS:Ag+,Cl˜
(Y,Lu,Gd)2_nCanSi4N6+nCl_n:Ce3+, (wherein OSn̂O.5)
(Lu,Ca,Li,Mg,Y)alpha-SiAlON doped with Eu2+ and/or Ce3+
(Ca,Sr,Ba)SiO2N2:Eu2+,Ce3+
(Sr,Ca)AlSiN3:Eu2+
CaAlSi(ON)3:Eu2+
Sr10(PO4)6Cl2:Eu2+
(BaSi)O12N2:Eu2+

While the above is a full description of the specific embodiments, various modifications, alternative constructions and equivalents may be used. Additionally, the above has been generally described in terms of one or more entities that may be one or more phosphor materials or phosphor like materials, but it would be recognized that other “energy-converting luminescent materials,” which may include one or more phosphors, semiconductors, semiconductor nanoparticles (“quantum dots”), organic luminescent materials, and the like, and combinations of them, can also be used. In other embodiments, the energy converting luminescent materials can be wavelength converting material and/or materials. Furthermore, the above has been generally described in electromagnetic radiation that directly emits and interacts with the wavelength conversion materials, but it would be recognized that the electromagnetic radiation can be reflected and then interact with the wavelength conversion materials or a combination of reflection and direct incident radiation. Therefore, the above description and illustrations should not be taken as limiting the scope of the invention which is defined by the appended claims.

What is claimed is:

1. An optical device comprising:
a mounting member having a surface region;
at least one LED device overlying a portion of the surface region;
a wavelength conversion material disposed over at least a portion of the surface region;
a wavelength selective surface configured to reflect substantially direct emission of the LED device and transmit a selected wavelength of converted emission caused by an interaction of the wavelength conversion material and the direct emission of the LED device;
wherein at least 30% of the direct emission from the LED device is reflected from the wavelength selective surface prior to interacting with the wavelength conversion material.

2. The optical device of claim 1 wherein the wavelength material has a thickness of less than 100 um.

3. The optical device of claim 1 wherein the surface region has a reflectivity greater than 50% at one or more of the emission wavelengths.

4. The optical device of claim 1 wherein the wavelength conversion material comprises wavelength conversion particles characterized by an average particle-to-particle distance of about less than 10 times the average particle size of all the wavelength-conversion materials.

5. The optical device of claim 1 wherein the wavelength selective surface comprises a filter.

6. The optical device of claim 1 wherein the wavelength selective surface comprises a dichroic optical member.

7. The optical device of claim 1 wherein the wavelength conversion material comprises a first wavelength-conversion material and a second wavelength-conversion material arranged in a pixilated pattern.

8. The device of claim 1 wherein the wavelength conversion material comprises a first wavelength-conversion material stacked on top of a second wavelength-conversion material.

9. The device of claim 1 wherein the wavelength conversion material comprises a first wavelength-conversion material mixed with a second wavelength-conversion material.

10. The device of claim 1 wherein the wavelength conversion material comprises a first wavelength-conversion material and a second wavelength-conversion material.

11. The optical device of claim 1 wherein the wavelength conversion material comprises one of a plurality of quantum dots, a phosphor material, and an organic material.

12. The optical device of claim 1 wherein the at least one LED device is fabricated on gallium and nitrogen containing substrate.

13. The optical device of claim 12 wherein the gallium and nitrogen containing substrate is characterized by a semi-polar or non-polar orientation.

14. An optical device comprising:
a mounting member comprising a surface region;
at least one LED device disposed over a portion of the surface region, the LED device having a top LED surface area;
a layer of wavelength conversion material disposed over a portion of the surface region;
a wavelength selective surface configured to reflect substantially direct emission of the LED device and configured to transmit selected wavelengths of converted emission caused by an interaction with at least the layer of wavelength conversion material and the direct emission of the LED device;
a first volume formed by the LED surface area and a first height connecting the LED surface area and the wavelength selective surface;
a second volume formed by an area of the layer of wavelength conversion material and a second height connecting the layer of wavelength conversion material and wavelength selective surface, the second volume being greater than the first volume, the second region being substantially transparent and substantially free from wavelength conversion materials.

15. The optical device of claim 14 wherein:
the LED devices has surface regions and characterized by a first height from a reference region;
the wavelength conversion material has an upper surface of a second height from the reference region; and
the second height is less than the first height.

16. The optical device of claim 14 wherein the wavelength conversion material comprises wavelength conversion particles characterized by an average particle-to-particle distance of about less than 10 times the average particle size of all the wavelength-conversion materials.

17. The optical device of claim 14 wherein the wavelength selective surface comprises a filter.

18. The optical device of claim 14 wherein the wavelength conversion material comprises a plurality of quantum dots, phosphor material, or organic material.

19. The optical device of claim 14 wherein the at least one LED devices are fabricated on gallium and nitrogen containing substrate.

20. The optical device of claim 19 wherein the gallium and nitrogen containing substrate is characterized by a semi-polar or non-polar orientation.
